(19) United States
(12) Patent Application Publication
(10) Pub. No.: US 2007/0159209 A1
(43) Pub. Date: Jul. 12, 2007

(54) METHOD OF MEASURING CAPACITANCE CHARACTERISTICS OF A GATE OXIDE IN A MOS TRANSISTOR DEVICE

(76) Inventor: Chul Soo Kim, Seoul (KR)

Correspondence Address: SHERR & NOURSE, PLLC, 620 HERNDON PARKWAY, SUITE 200, HERNDON, VA, 20170, US

(21) Appl. No.: 11/615,772

(22) Filed: Dec. 22, 2006

(30) Foreign Application Priority Data
Dec. 29, 2005 (KR) 10-2005-0134153

(51) Int. Cl. G01R 31/26

(52) U.S. Cl. 324/769

(57) ABSTRACT

A method for measuring capacitance characteristics of a gate oxide in MOS transistor device. Capacitance characteristics of a gate oxide may be accurately, rapidly, and effectively obtain (e.g. in the form of a capacitance characteristics curve). A method may measure capacitance characteristics of a gate oxide using a characteristics measuring system using an impedance Z—phase angle θ method.

The present application claims priority under 35 U.S.C. 119 and 35 U.S.C. 365 to Korean Patent Application No. 10-2005-0134153 (filed on Dec. 29, 2005), which is hereby incorporated by reference in its entirety.

### BACKGROUND

A MOS transistor may be a semiconductor device, which may be activated by a charge accumulated in a channel using a gate oxide. A method may measure capacitance characteristics of a gate oxide in a MOS transistor device. A method may measure capacitance characteristics by using capacitor measuring devices (e.g. a LCR meter) with a specific frequency and gate voltage. Gate leakage current and a dissipation factor may become relatively high due to a length of a gate being relatively short and/or a gate oxide being relatively thin. There may be complications in capacitance of a MOS transistor due to the thickness of a gate oxide being relatively thin. It may be relatively difficult to measure the capacitance characteristics of a gate oxide.

### SUMMARY

Embodiments relate to a method of measuring capacitance characteristics of a gate oxide in MOS transistor device. In embodiments, capacitance characteristics of a gate oxide may be accurately, rapidly, and effectively obtain (e.g. in the form of a capacitance characteristics curve). In embodiments, a method may measure capacitance characteristics of a gate oxide using a characteristics measuring system using an impedance Z—phase angle θ method.

In embodiments, a method of measuring capacitance characteristics of a gate oxide in a MOS transistor device, may include at least one of: mounting a measurement object wafer in a probe station connected to a capacitance measuring unit and electrically connecting the measurement object wafer to the probe station; eliciting impedance-frequency and phase-frequency relation by measuring impedance and phase angle while setting up a wafer using a capacitance measuring unit using pre-adjusted gate voltage and changing frequency; and/or extracting gate capacitance using measured data.

### BRIEF DESCRIPTION OF THE DRAWINGS

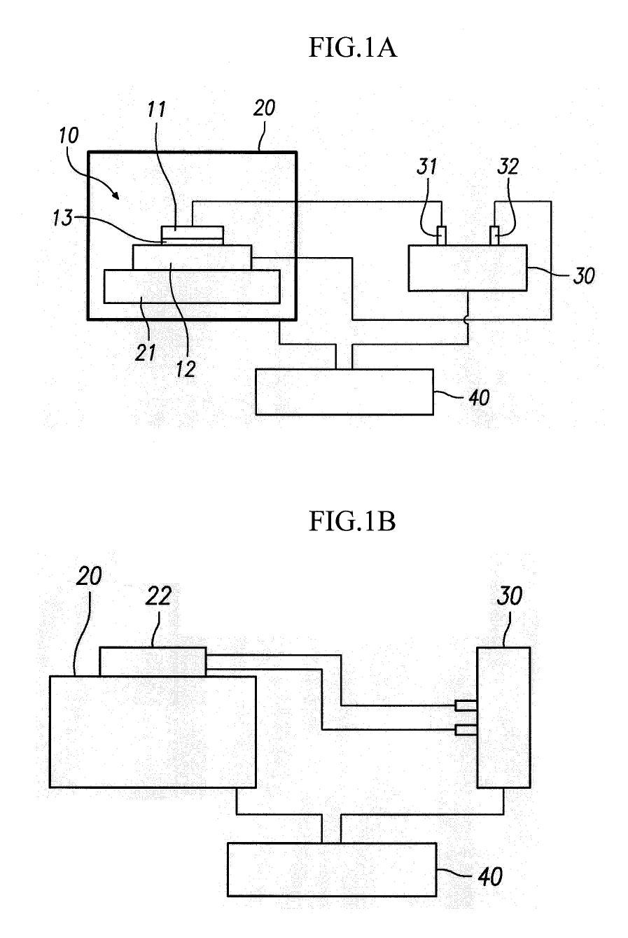

Example FIGS. 1a and 1b illustrate a characteristics measuring system which measures a MOS transistor device, in accordance with embodiments.

### DETAILED DESCRIPTION

Embodiments relate to a method of measuring capacitance characteristics of a gate oxide in a MOS transistor device. Embodiments relate to a measuring system configured to measure capacitance characteristics of a gate oxide in a MOS transistor device. In embodiments, an expression “on” may mean that something is formed directly on another thing or indirectly formed by intervening in another layer in case of disclosing the formation “on” respective layers.

FIG. 1a illustrates a system which measures carrier density distribution of a MOS transistor device using an Automatic Test System in a Manual Test System, in accordance with embodiments. In embodiments, measurement and analysis procedures may be automated. In embodiments, mechanical operations (e.g. a procedure which loads a wafer pn a Probe Station in a Manual Test System may be manually performed and/or automated.

FIG. 1b illustrates a system for measuring carrier density distribution of a MOS transistor device, in accordance with embodiments. In embodiments, a system may us an Automatic Test System in an automatic DC Parametric Test System.

As illustrated in FIGS. 1a and 1b, wafer 10 (which may be a measurement target) may be positioned over chuck 21 inside probe station 20. High frequency terminal 31 of capacitance measuring unit 30 (e.g. a LCR meter) may be connected to gate 11 of wafer 10. Low frequency terminal 32 may be connected to substrate 12 of wafer 10. Probe station 20 and capacitance measuring unit 30 may be connected to control computer 40.

Probe station 20 illustrated in FIG. 1a may be connected to a measuring device using a probe. Probe station 20 of FIG. 1b may use probe card 22. Capacitance measuring unit 30 may use an automatic DC Parametric Test System.

In embodiments, probe station 20 may be shielded from external influences using a dark box or a shielding box. A dark box or a shielding box may prevent measurement distortion caused by external light and/or electromagnetic waves.

Embodiments relate to a method of measuring capacitance characteristics of a gate oxide in a MOS transistor device. Wafer 10 may be mounted inside of probe station 20. Wafer 10 may be electrically connected to probe station 20 by either a probe or a probe card. Capacitance measuring unit 30 may deliver a pre-adjusted gate voltage Vg to gate 11, in accordance with embodiments. Through delivery of gate voltage Vg, impedance-frequency and/or phase-frequency relation curves may obtained.

In embodiments, Minimum ωₘᵢₙ of a frequency may be defined according to Equation 1, as follows.

$${ω}_{min} = \frac{1}{{R}_{P} {C}_{P}} \sqrt{\frac{{R}_{S} + {R}_{P}}{{R}_{P} + 3 {R}_{S}}} , \qquad [ Equation 1 ]$$

In Equation 1, Rₚ may denote a resistance voltage value of a gate oxide, Rₛ may denote a resistance voltage value of a substrate, and Cₚ may denote a capacitance of a gate oxide.

The capacitance of a gate may be ascertained from impedance-frequency and/or phase-frequency relation curves, in accordance with embodiments. In embodiments, the capacitance of a gate may be ascertained using a parameter extraction tool.

In embodiments, gate voltage Vg may be changed and an impedance-frequency and phase-frequency relation curve may obtained for the changed gate voltage Vg. A gate capacitance may be determined from impedance-frequency and/or phase-frequency relation curves of at least one gate voltage Vg, in embodiments. A gate capacitance may be elicited from an inversion region to an accumulation region by fitting data obtained through in impedance-frequency and/or phase-frequency relation curves. In embodiments, capacitance characteristics of a gate oxide may be determined from a gate capacitance.

In embodiments, a method measures capacitance characteristics of a gate oxide in a MOS transistor device. In embodiments, relatively accurate data associated with capacitance characteristics of a gate oxide may be obtained (e.g. in a relatively short time) by utilizing characteristics measuring system using an impedance-phase angle method. In embodiments, statistic analysis corresponding to capacitance characteristics of a gate oxide may be performed.

It will be apparent to those skilled in the art that various modifications and variations can be made to embodiments. Thus, it is intended that embodiments cover modifications and variations thereof within the scope of the appended claims.

What is claimed is:

1. A method comprising measuring a capacitance of a gate oxide of a transistor formed in a substrate from at least one of an impedance-frequency measurement and a phase-frequency measurement.

2. The method of claim 1, wherein the said measuring the capacitance of the gate oxide is from both the impedance-frequency measurement and the phase-frequency measurement.

3. The method of claim 1, wherein a voltage is applied to a gate of the transistor during said at least one of the impedance-frequency measurement and the phase-frequency measurement.

4. The method of claim 3, wherein the frequency the gate voltage is varied during said at least one of the impedance-frequency measurement and the phase-frequency measurement.

5. The method of claim 4, wherein the frequency has a minimum frequency ωₘᵢₙ, defined by:
$${ω}_{min} = \frac{1}{{R}_{P} {C}_{P}} \sqrt{\frac{{R}_{S} + {R}_{P}}{{R}_{P} + 3 {R}_{S}}} ,$$
wherein, Rₚ denotes a resistance voltage value of the gate oxide, Rₛ denotes a resistance voltage value of the substrate, and Cₚ denotes capacitance of the gate oxide.

6. The method of claim 3, wherein the voltage is changed in different sets of said at least one of the impedance-frequency measurement and the phase-frequency measurement.

7. The method of claim 1, wherein:
the transistor is formed in a wafer;
the wafer is mounted in a probe station; and
the probe station is connected to a capacitance measuring unit.

8. The method of claim 1, wherein measuring the capacitance of the gate oxide uses a parameter extraction tool.

9. An apparatus configured to measure a capacitance of a gate oxide of a transistor formed in a substrate, wherein the apparatus is configured to measure the capacitance from at least one of an impedance-frequency measurement and a phase-frequency measurement.

10. The apparatus of claim 9, wherein the capacitance of the gate oxide is measured from both the impedance-frequency measurement and the phase-frequency measurement.

11. The apparatus of claim 9, wherein the apparatus is configured to apply a voltage to a gate of the transistor during said at least one of the impedance-frequency measurement and the phase-frequency measurement.

12. The apparatus of claim 11, wherein the frequency the gate voltage is varied during said at least one of the impedance-frequency measurement and the phase-frequency measurement.

13. The apparatus of claim 12, wherein the frequency has a minimum frequency ωₘᵢₙ, defined by:
$${ω}_{min} = \frac{1}{{R}_{P} {C}_{P}} \sqrt{\frac{{R}_{S} + {R}_{P}}{{R}_{P} + 3 {R}_{S}}} ,$$
wherein, Rₚ denotes a resistance voltage value of the gate oxide, Rₛ denotes a resistance voltage value of the substrate, and Cₚ denotes capacitance of the gate oxide.

14. The apparatus of claim 11, wherein the voltage is changed in different sets of said at least one of the impedance-frequency measurement and the phase-frequency measurement.

15. The apparatus of claim 9, wherein:
the transistor is formed in a wafer;
the wafer is mounted in a probe station of the apparatus; and
the probe station is connected to a capacitance measuring unit of the apparatus.

16. The apparatus of claim 9, wherein the apparatus comprises a parameter extraction tool configured to measure the capacitance of the gate oxide.
